(19) United States
(12) Patent Application Publication
(10) Pub. No.: US 2025/0062770 A1
(43) Pub. Date: Feb. 20, 2025

(54) PHASE-LOCK LOOP USING PHASE CONVERGENCE COMPENSATION

(71) Applicant: NXP B.V., Eindhoven (NL)

(72) Inventors: Mathieu Périn, Cairon (FR); Stefano Dal Toso, Antibes (FR); Khurram Waheed, Austin, TX (US)

(21) Appl. No.: 18/799,117

(22) Filed: Aug. 9, 2024

(30) Foreign Application Priority Data
Aug. 14, 2023 (EP) 23306373.4

(51) Int. Cl. H03L 7/107; H03L 7/093; H03L 7/099

(52) U.S. Cl. CPC H03L 7/1075; H03L 7/093; H03L 7/0994

(57) ABSTRACT

Provided is a phase-lock loop that includes: an oscillator having an input for receiving a control signal and an output for providing an output signal having a frequency based on the control signal; a phase detector having a first input for receiving a reference signal, a second input coupled to the output of the oscillator for receiving a feedback signal, and an output for providing a phase-error signal that is indicative of a phase difference between the reference signal and the feedback signal; and a loop filter having a first input coupled to the output of the phase detector, a second input for receiving a proportional-phase-compensation value, and an output for providing the control signal to the oscillator. The control signal comprises a proportional component which is a combination of the phase-error signal and the proportional-phase-compensation value.

### FIELD OF THE INVENTION

The present invention pertains, among other things, to systems, apparatuses, methods and techniques, e.g., for achieving fast locking times in a phase-lock loop (PLL) using phase compensation.

### BACKGROUND

The following discussion concerns certain background information related to the present invention. However, it should be understood that only knowledge clearly, explicitly and specifically described herein as being “conventional” or “prior art” is intended to be characterized as such. Everything else should be understood as knowledge and/or insight originating from the present inventors.

PLLs commonly are used in situations in which a periodic signal source that is highly controlled in frequency and phase is desired. The basic structure of an exemplary conventional digital PLL (DPLL) 10 is illustrated in FIG. 1. As shown, DPLL 10 includes a frequency-controllable oscillator, here a Digitally Controlled Oscillator (DCO) 12 which produces a periodic output signal such as a sinusoid, a square wave, a digital CMOS clock (analog) output signal 13 based on a digital control signal 14, usually referred to herein as a normalized oscillator tuning word (NOTW), which is then scaled to provide an oscillator tuning word (OTW) that is directly used by the DCO 12 (not shown in the drawings for sake of simplicity). That digital control signal 14, in turn, is generated based on a digital reference signal 15 (typically, a digital clock signal), together with a modulation frequency control word (FCW) 16 and a channel FCW 17 that, together, specify how the output signal 13 is intended to be related to the digital reference signal 15, and also is based on a feedback signal 21 (discussed in greater detail below).

For precise control of the output signal 13, a feedback path 20 is provided, in which phase information 21 regarding the output signal 13, generated by module 22, is provided to a digital phase detector 24 which, in turn, compares such phase information 21 to the reference signal 15 in order to identify and output a signal 25 indicating any phase error. Phase error signal 25 is then processed in digital filter 35 and used to provide the digital control signal 14 to DCO 12 in a manner calculated to reduce the phase error signal 25. Module 22 can have any of a variety of different implementations, e.g., so as to provide a counter-based DPLL or a divider-based DPLL, with or without phase prediction.

Upon startup of the DPLL 10, the phase error signal 25 often is quite large. Conventionally, it can take a significant amount of time for the phase error to reach an acceptably small level, at which point the DPLL 10 is considered locked, and the feedback loop 20 then keeps the phase error at that small level, at least until there is some disruption that requires a re-locking.

A conventional DPLL 10 can operate in any of several different modes. Those operational modes generally can be described with reference to control structure 40 (which includes digital phase detector 24 and digital loop filter 35). In many applications, a fast PLL locking time is highly desirable, e.g., to reduce power consumption and to enable fast turn-around times within radios. Reduction in locking time is particularly important for some applications, such as narrowband Bluetooth Low-Energy (LE) Channel Sounding.

Due to its faster locking-time characteristics, it is common for PLLs to start a locking sequence in Type-I operation, which uses only a proportional loop filter. FIG. 2 shows a conventional proportional control structure 50, which can be used as control structure 40 of DPLL 10 when in Type-I operation. As indicated, it is a fairly straightforward implementation of control structure 40, with the phase error signal 25 (sometimes referred to as PHE or, more specifically with respect to these conventional embodiments, PHE_{NO-COMP}) that is output from digital phase detector 54 (which is a specific implementation of digital phase detector 24) simply supplied to the digital loop filter 55 (which is a specific implementation of digital loop filter 35). Digital loop filter 55 then typically low-pass filters it (not shown) to reduce noise and applies a loop gain 57 of a, which typically is selected as a trade-off between response time and noise sensitivity.

Depending on the mission-mode requirements of the PLL, the PLL might switch to either Pseudo-Type-II or Type-II operation. Each such operational mode incorporates an integrator (or accumulator, with each reference to either such term herein being replaceable by a reference to the other) in addition to the inherent integrator in the DCO 12, with such additional integrator typically being provided in the loop filter 35. In this regard, it is noted that engaging an integrator in the loop, while generally better for maintaining lower average phase error during steady-state operation, can significantly slow locking time. Also, the present inventors have discovered that dynamically switching between PLL operational modes within conventional systems often can significantly increase locking time.

FIG. 3 shows a conventional control structure 60, which can be used as control structure 40 of DPLL 10 when in true Type-II operation (locking to a null phase error). Here, an integrator 66 is incorporated into the digital loop filter 65 (which is another specific implementation of digital loop filter 35), and the phase error signal (PHE) 25 is provided both: to the proportional part of the digital loop filter 65 (this line being labeled as PHE_{P} 25A in FIG. 3), where it is simply scaled by a gain 67 of α; and to the integrator 66 after being multiplied by a gain 68 of ρ, (this line being labeled as PHE_{I} 25B in FIG. 3). Note that integrator 66 includes an enable/disable input 69, so that filter 65 can be operated in Type-I or Type-II mode. Also, as with digital loop filter 55, discussed above, the overall digital loop filter 35 that includes filter 65 typically includes one or more low-pass filters (not shown) to reduce noise.

FIG. 4 shows a conventional control structure 70, which can be used as control structure 40 of DPLL 10 when in Pseudo-Type-II operation, which essentially is a variation on classical Type-II operation. In this operational mode, the PLL operates in Type-II class (i.e., its digital loop filter 75, which is a specific implementation of digital loop filter 35, includes: an integrator 76, corresponding to integrator 66; gain elements 77 and 78, corresponding to gain elements 67 and 68, respectively; and, typically, one or more low-pass filters (not shown) to reduce noise). However, control structure 70 operates with an offset phase error. That is, the steady-state phase error in this operational mode is different than zero. Instead, the overall DPLL locks to a phase error 25 that is based on an identified target phase error 71 (sometimes referred to as PHE_{TARGET}), e.g., PHE=−PHE_{TARGET}. Generally speaking, the main idea behind Pseudo-Type-II operation is for the PLL to lock to an arbitrary target, rather than locking to 0 (as in classical Type-II operation). If PHE 25 is close to −PHE_{TARGET}, the integrator 76 need only track small errors/noise, and the impact on locking time can be almost negligible. In that particular case, by exploiting this property, the locking time typically is faster than when operating in classical Type-II mode.

### SUMMARY OF THE INVENTION

One embodiment of the invention is directed to a phase-lock loop that includes: an oscillator having an input for receiving a control signal and an output for providing an output signal having a frequency based on the control signal; a phase detector having a first input for receiving a reference signal, a second input coupled to the output of the oscillator for receiving a feedback signal, and an output for providing a phase-error signal that is indicative of a phase difference between the reference signal and the feedback signal; and a loop filter having a first input coupled to the output of the phase detector, a second input for receiving a proportional-phase-compensation value, and an output for providing the control signal to the oscillator. The control signal comprises a proportional component which is a combination of the phase-error signal and the proportional-phase-compensation value.

Another embodiment is directed to a tangible medium storing computer-readable, computer-executable process steps for controlling a phase-lock loop that includes an adder having a first input coupled to a phase-error signal output by phase-detector, a second input, and an output that provides a proportional-phase-compensation value. The process steps include steps to: begin operating the phase-lock loop in a first operational phase, during which a first value is provided to the second input of the adder; and after a first period of time, instead providing a second value to the second input of the adder. The second value is based on the phase-error signal during the first operational phase.

Certain more-specific implementations of either of the foregoing embodiment(s) include one or any combination of the following features.

The proportional component is produced by adding the phase-error signal and the proportional-phase-compensation value to provide a result and then applying a gain to the result.

The proportional-phase-compensation value has been determined based on a previous value of the phase-error signal.

The phase-compensation value has been determined based on an average of previous values of the phase-error signal.

The proportional-phase-compensation value has been determined by low-pass filtering the phase-error signal during a prior operational period of the phase-lock loop.

The proportional-phase-compensation value has been determined mathematically, in advance, based on loop characteristics.

The phase-lock loop begins operating in a first operational phase, during which the proportional-phase-compensation (PPC) value is set at a first PPC value, and after a first period of time, the proportional-phase-compensation value is updated to a second PPC value based on the phase-error signal during the first operational phase. The first PPC value is 0.

The first PPC value has been determined mathematically, in advance, based on loop characteristics.

The second PPC value is determined by at least one of: (a) averaging values of the phase-error signal (e.g., moving average, time-windowed accumulator, average filter, etc.) during at least a portion of the first operational phase, or (b) low-pass filtering the phase-error signal during at least a portion of the first operational phase.

The loop filter also includes an integrator which, when enabled, provides an integral component of the control signal, and wherein the integrator is disabled, such that the integral component is 0, until satisfaction of a specified criterion following completion of the first period of time, at which point the integrator is enabled.

The specified criterion comprises the end of a predetermined additional second period of time.

The specified criterion comprises a condition on the phase-error signal after the proportional-phase-compensation value has been updated to the second value.

The specified criterion comprises at least one of: (a) a magnitude of at least one value of the phase-error signal falling within a specified range; or (b) variation in the phase-error signal falling below a specified threshold.

When the integrator is enabled, the integrator accumulates uncompensated values of the phase-error signal.

When the integrator is enabled, the integrator accumulates modified phase-error signal values that are a combination of the phase-error signal and an integral-phase-compensation (IPC) value.

The integral-phase-compensation value is determined based on the phase-error signal during the first operational phase.

A characteristic phase value is determined based on the phase-error signal during the first operational phase; the integral-phase-compensation value is set at a multiple of 2× in a phase-domain representation; and the second PPC value is set as a difference between the characteristic phase value and the integral-phase-compensation value.

The integral-phase-compensation value is set to the multiple of 2× in a phase-domain representation nearest to the characteristic phase value.

The foregoing summary is intended merely to provide a brief description of certain aspects of the invention. A more complete understanding of the invention can be obtained by referring to the claims and the following detailed description of the preferred embodiments in connection with the accompanying figures.

### BRIEF DESCRIPTION OF THE DRAWINGS

In the following disclosure, the invention is described with reference to the accompanying drawings. However, it should be understood that the drawings merely depict certain representative and/or exemplary embodiments and features of the present invention and are not intended to limit the scope of the invention in any manner. The following is a brief description of each of the accompanying drawings.

FIG. 1 is a simplified block diagram of a conventional digital phase-lock loop (DPLL).

FIG. 2 is a block diagram of a conventional proportional control structure for use in Type-I phase-lock loop (PLL) operation.

FIG. 3 is a block diagram of a conventional proportional integral control structure for use in Type-II PLL operation.

FIG. 4 is a block diagram of a conventional proportional biased-integral control structure for use in Pseudo-Type-II PLL operation.

FIG. 5 is a block diagram of a compensated proportional control structure for use in Type-I digital phase-lock loop (DPLL) operation according to a representative embodiment of the present invention.

FIG. 6 is a flow diagram illustrating an exemplary process for operating a control structure in Type-I mode according to a representative embodiment of the present invention.

FIG. 7 is a block diagram of a compensated proportional integral control structure for use in Type-II DPLL operation according to a representative embodiment of the present invention.

FIG. 8 is a flow diagram illustrating an exemplary process for operating a control structure in Type-II mode according to a representative embodiment of the present invention.

FIG. 9 is a block diagram of a compensated proportional integral control structure for use in Pseudo-Type-II DPLL operation according to a representative embodiment of the present invention.

FIG. 10 is a flow diagram illustrating an exemplary process for operating a control structure in Pseudo-Type-II mode according to a representative embodiment of the present invention.

FIG. 11 is a block diagram of a proportional integral (PI) controller (PIC) according to a representative embodiment of the present invention.

### DESCRIPTION OF THE PREFERRED EMBODIMENT(S)

For ease of reference, the present disclosure is divided into sections. The general subject matter of each section is indicated by that section's heading. However, such headings are included simply for the purpose of facilitating readability and are not intended to limit the scope of the invention in any manner whatsoever.

### Overview.

The present inventors have discovered that improvements can be made to the conventional PLL locking techniques and structures discussed above. In the preferred embodiments of the present invention, an efficient fast-locking PLL is achieved using techniques to speed up the convergence trajectory exhibited by conventional PLLs. For this purpose, a digital PLL (DPLL) is preferred in the present invention (and is assumed throughout this disclosure), e.g., because such a PLL allows for easier dynamic reconfiguration between operational modes (e.g., from a Type-I operational mode to a Pseudo-Type-II or Type-II operational mode). However, except to the extent clearly and explicitly noted otherwise, the present invention is not intended to be limited to DPLLs. As discussed in greater detail below, the present invention can provide efficient implementations to accomplish fast locking in all Type-I, Type-II and Pseudo-Type-II operational modes of a PLL. In one respect, the present invention provides novel PLL convergence compensation techniques and/or apparatuses to achieve an efficient locking solution for the various PLL operational modes.

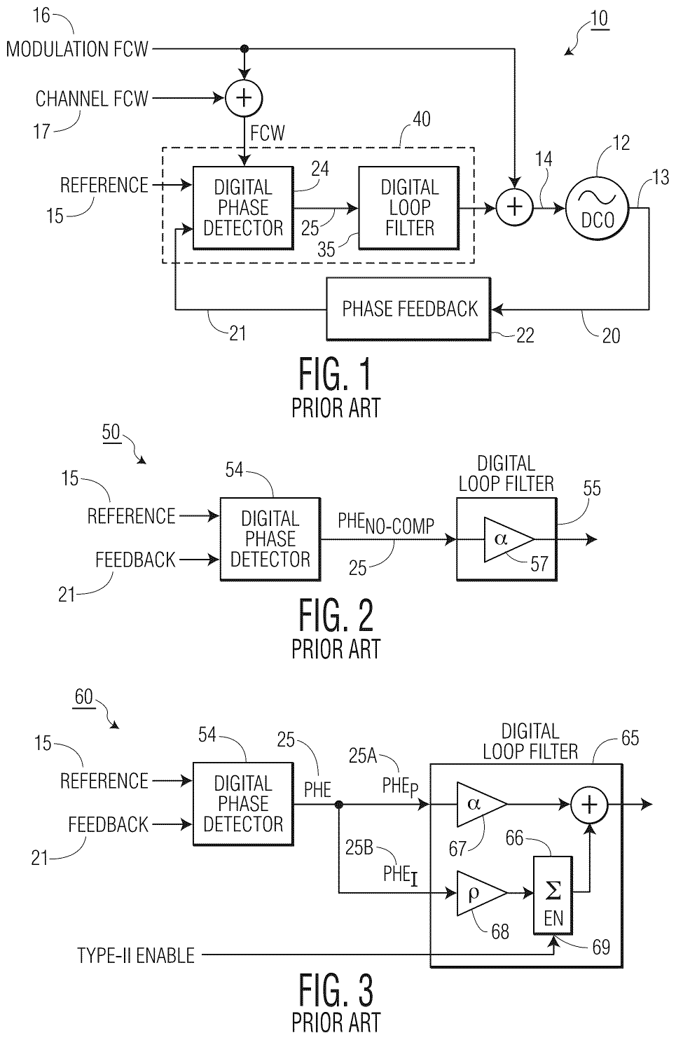

In most of the preferred embodiments, a system according to the present invention estimates the proportional phase error: (1) during an initial lock in Type-I PLL operation and/or (2) using a mathematically predicted value (e.g., in advance, based on mathematical calculations with knowledge of some or all of the loop parameters and/or characteristics), and then uses this estimated phase error (sometimes referred to as PHE_{COMP}) to compensate, either in a feedforward manner or just by offset compensation, either the proportional path (for subsequent/continued Type-I operation) or both the proportional and integral paths (for subsequent Type-II or Pseudo-Type-II operation of the PLL). Referring again to FIG. 1, the preferred embodiments of the present invention can be described mainly in reference to improvements in the control structure 40 (which includes digital phase detector 24 and digital loop filter 35) of a conventional DPLL 10, especially its digital loop filter 35, as discussed in greater detail below.

### Type-I Operation.

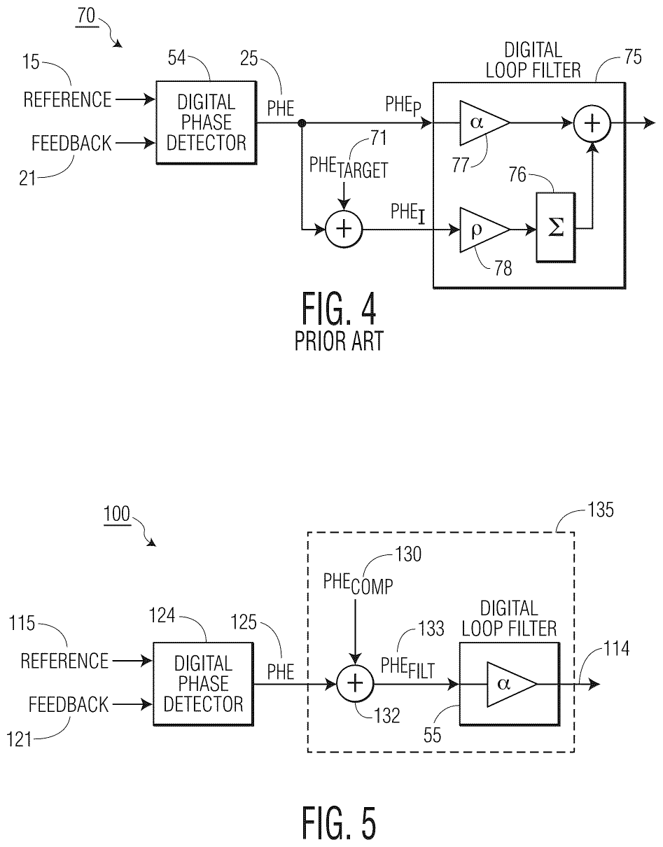

FIG. 5 is a block diagram of a proportional control structure 100 for use in Type-I operation of a PLL according to the present invention. Generally speaking, control structure 100 can replace structure 40 in DPLL 10. In this embodiment, the phase error signal (PHE) 125 (output from phase detector 124, based on feedback signal 121 and reference signal 115, e.g., as discussed above) is combined with a previously determined phase compensation value (PHE_{COMP}) 130 in adder 132, thereby providing PHE_{FILT} 133, which is then supplied to digital loop filter 55 (or, e.g., another implementation of digital loop filter 35), which in turn, outputs a NOTW 114. Preferably, when the compensation PHE_{COMP} 130 is applied: PHE_{FILT}=PHE_{NO-COMP}. It is noted that the foregoing structure (e.g., including a conventional digital loop filter 55 in combination with the foregoing application of phase compensation) can be considered to be a modified digital loop filter 135.

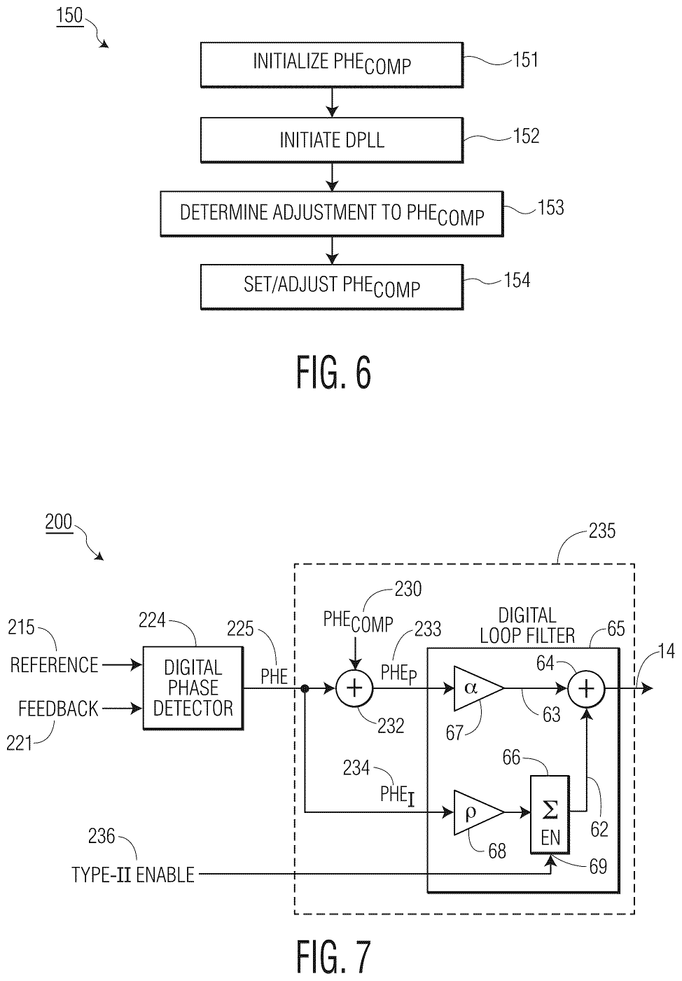

FIG. 6 illustrates an exemplary process 150 for operating the control structure 100, e.g., including the setting of certain control and/or input signals by one or more control processors (not shown). Initially, in step 151, PHE_{COMP} 130 is set to an initial value. In some embodiments, this initial value will be 0. However, in certain embodiments, the initial value of PHE_{COMP} 130 is determined mathematically based on knowledge of at least some of the feedback-loop parameters and/or characteristics and, therefore, can be (and preferably is) applied from the beginning of the locking sequence. One approach to such a mathematical determination is as follows.

If the DPLL is built to get a NOTW=0 for the mid-frequency (f_{mid}) that is being targeted for the application, e.g., 2442 MHz, and the DPLL currently is trying to lock to 2402 MHz, the frequency difference (Δf) is −40 MHz. If, either by design (not very robust) or due to an open-loop gain estimation of the DCO (using a two-point frequency measurement and gain computation as an example), the K_{DCO} gain value is known, and because the reference frequency value (fref) of the DPLL and the a proportional gain coefficient that is applied also are known, then the compensation value can be calculated as follows:

$${f}_{DCO} = {f}_{mid} + {K}_{DCO} * OTW , where OTW = NOTW * {f}_{ref} / {K}_{DCO , estimated}$$

$${NOTW}_{P} = PHE * α$$

$$For {f}_{DCO} = {f}_{mid} ( = 2442 MHz in our example ) then OTW = 0 , NOTW = 0 and PHE = 0$$

$$For now , {f}_{DCO} = 2402 MHz \to OTW = ( {f}_{DCO} - {f}_{mid} ) / {K}_{DCO} \to NOTW = OTW * {K}_{DCO , estimated} / {f}_{ref} = ( {f}_{DCO} - {f}_{mid} ) / {K}_{DCO} * {K}_{DCO , estimated} / {f}_{ref} \approx ( {f}_{DCO} - {f}_{mid} ) / {f}_{ref}$$

$${PHE}_{COMP} = NOTW / α = ( {f}_{DCO} - {f}_{mid} ) / {K}_{DCO} * {K}_{DCO , estimated} / {f}_{ref} / α \approx ( {f}_{DCO} - {f}_{mid} ) / {f}_{ref} / α \approx Δ f / {f}_{ref} / α$$

So assuming a Δf of −40 MHz, a reference frequency of 40 MHz and an α coefficient of 8 (corresponding to a value of 8*2× in a phase-domain representation), the PHE_{COMP}=−8

In step 152, the DPLL of which control structure 100 is a part is initiated. In the preferred embodiments, steps 153 and 154 are then performed. However, in some embodiments, especially some embodiments in which the initial value of PHE_{COMP} 130 was determined mathematically in step 151, steps 153 and 154 are omitted. In the current embodiment, steps 153 and 154 are performed, as follows.

In step 153, the value (or an adjustment to the value) of PHE_{COMP} 130 is estimated based on actual value(s) of PHE 125 as the DPLL is operated in the foregoing initial phase of its operation. Depending e.g., upon the particular embodiment, this value (sometimes referred to herein as a characteristic phase value) is determined in any of a variety of different ways. Examples include determining the value as, or based on: (1) a simple snapshot of the PHE 125 value at a specified point in time; (2) a moving average of the PHE 125 values completed at a specified point in time; (3) any other averaging of the PHE 125 values; (4) any low-pass filtering (finite impulse response or infinite impulse response) of the PHE 125 values after a specified period of time; or (5) any combination of any of the foregoing techniques. In the currently preferred embodiment, a simple averaging approach is used, implemented using a time-windowed accumulator across a number of samples that is a power of two (more preferably, 128 samples), followed by a right shift by a corresponding number of bits (e.g., a 7-bit rightward shift in this example).

Finally, in step 154, the value of PHE_{COMP} 130 is set or adjusted, as applicable, based on the value determined in step 153. Preferably, this step is performed by simply adding the value determined in step 153 to the previous value of PHE_{COMP} 130.

As indicated in the preceding discussion, certain embodiments of the invention set the value of PHE_{COMP} 130 solely based on a mathematical calculation based on knowledge of at least some of the loop parameters and/or characteristics, which can be done at the outset, prior to the operation of the DPLL. Other embodiments determine PHE_{COMP} 130 solely based on previous values of previous value(s) of PHE 125 (e.g., during an initial phase or period of operation). Still further embodiments utilize a combination of these techniques. For instance, in certain embodiments PHE_{COMP} 130 is determined mathematically at the outset, and then that value is used until a more accurate value can be estimated based on actual previous value(s) of PHE 125.

It is noted that during Type-I operation, PHE is unbound. However, in the preferred embodiments, because PHE=PHE_{FILT}−PHE_{COMP}, the phase error PHE 125 can be chosen to be any value, depending on the selected PHE_{COMP} value 130. As a result, e.g., when compensation is applied, the phase error PHE 125 often can be brought within the range of the phase detector 124. In the preferred embodiments, PHE_{COMP} 130 has been estimated or calculated earlier, e.g., in one of the foregoing ways.

It is also noted that, in some applications, limiting the range of the phase detector 124 can help in reducing overall power consumption. Accordingly, in some embodiments, DPLL is started with a wider-range phase-detector 124, which is used to estimate the value of PHE_{COMP} 130. Such initial wider-range phase detector preferably is then no longer used after such estimation has been completed, in order to reduce power consumption, and a narrower-range phase-detector 124 instead is used along with the present phase-compensation structure/technique (with the phase error 125 now being within such reduced phase-detector range).

In the event a re-locking is required, process 150 preferably is repeated in its entirety.

### Type-II Operation.

FIG. 7 is a block diagram of a compensated proportional integral control structure 200 for use in Type-II operation of a PLL according to the present invention. Generally speaking, control structure 200 can replace control structure 40 in DPLL 10.

Similar to the previous embodiment, in this embodiment, the phase error signal (PHE) 225 (output from phase detector 224, based on feedback signal 221 and reference signal 215, e.g., as discussed above) is combined with a previously determined (proportional) phase compensation value (PHE_{COMP}) 230 in adder 232, thereby providing the proportional part of the phase error (PHE_{P}) 233, which is then coupled to gain element 67 of digital loop filter 65 (or, e.g., the proportional input of another digital loop filter 35), while phase error signal 225 is coupled (e.g., directly or without compensation) to gain element 68 of digital loop filter 65 (or, e.g., an integral input of another digital loop filter 35) as the integral part (PHE_{I}) 234 of the phase error. The output of gain element 68 is accumulated within accumulator 66 to provide NOTW_{I} signal 62 which is then combined with the NOTW_{P} signal 63 output from gain element 67 within adder 64 to provide NOTW signal 14. This entire structure (including the compensation to the proportional part of the phase error) can be considered to be a modified digital loop filter 235.

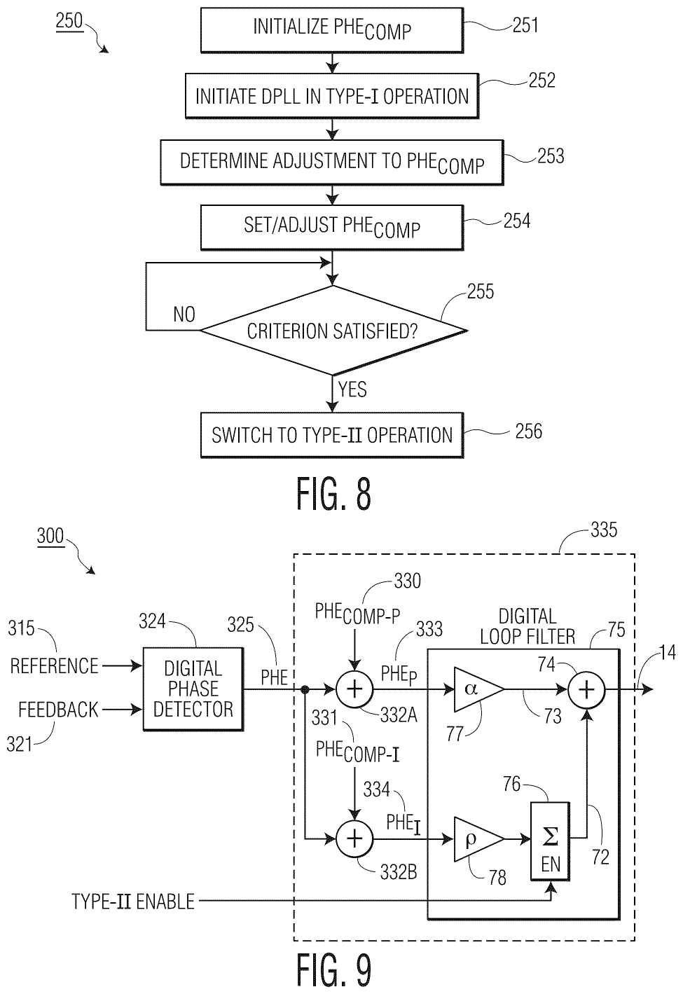

FIG. 8 illustrates an exemplary process 250 for operating the control structure 200, e.g., including the setting of certain control and/or input signals by one or more control processors (not shown). Initially, in step 251, PHE_{COMP} 230 is set to an initial value, e.g., similar to the setting of PHE_{COMP} 130 and/or with the same considerations applying.

In step 252, the DPLL of which control structure 200 is a part is initiated in Type-I operation, i.e., with integrator 66 disabled by control signal 236. Steps 253 and 254 preferably are then performed (e.g., depending upon the embodiment), with such steps preferably being similar to steps 153 and 154 (discussed above), respectively, and with the same considerations preferably applying.

In step 255, a determination is made as to whether a specified criterion has been satisfied. Depending upon the specific embodiment, such criterion preferably includes: (1) PHE 225 has come within a specified range (e.g., and remained there for a specified period of time or number of cycle(s)); (2) variation in PHE 225 has dropped to an acceptably low level (e.g., a specified measure of such variation is below a specified threshold for a specified period of time or number of cycle(s)); or (3) a sufficient period of time has passed (e.g., selected so as to ensure, or at least provide reasonable confidence, that variation in PHE 225 has dropped to an acceptably low level). In any event, if such specified criterion has been satisfied, then processing proceeds to step 256. If not, the process 250 waits at this step 255 until the criterion is satisfied. Optionally, a timeout feature is incorporated, pursuant to which every specified period of time without satisfaction of the criterion, the process 250 is reinitiated.

In step 256, the DPLL switches to Type-II operation, by using control signal 236 to enable the integrator 66.

Summarizing, in the preferred embodiments, control structure 200 is started in Type-I operation, i.e., with the integrator 66 disabled using control signal 236, and PHE_{COMP} 230 is estimated during such Type-I operational stage, e.g., using any of the techniques mentioned above in connection with control structure 100. Then, upon completion of such estimation, the identified value for PHE_{COMP} 230 is applied (or altered, e.g., if a mathematically calculated value was used initially), causing the value of PHE_{P} 233 to converge to a value close to zero. Shortly thereafter, the integrator 66 is enabled using signal 236, so that control structure 200 begins operating in Type-II mode, with the same value of PHE_{COMP} 230 being applied, thereby causing PHE 225 to converge to zero. Since the value of PHE 225 before enabling the integrator 66 was already close to zero, the settling time (i.e. the PLL locking time) typically is much shorter.

### Pseudo-Type-II Operation.

FIG. 9 is a block diagram of a compensated proportional integral control structure 300 for use in Pseudo-Type-II operation of a PLL according to the present invention. Generally speaking, control structure 300 can replace control structure 40 in DPLL 10.

In this embodiment, the phase error signal (PHE) 325 (output from phase detector 324, based on feedback signal 321 and reference signal 315, e.g., as discussed above) is combined with a previously determined proportional phase compensation value (PHE_{COMP-P}) 330 in adder 332A, thereby providing PHE_{P} 333, which is then coupled to proportional gain element 77 of digital loop filter 75 (or, e.g., a proportional input of another digital loop filter 35). Similarly, PHE 325 is combined with a previously determined integral phase compensation value (PHE_{COMP-I}) 331 in adder 332B, thereby providing PHE_{I} 334, which is then coupled to integral gain element 78 of digital loop filter 75 (or, e.g., an integral input of another digital loop filter 35). The output of gain element 78 is accumulated within accumulator 76 to provide NOTW_{I} signal 72 which is then combined with the NOTW_{P} signal 73 output from gain element 77 within adder 74 to provide NOTW signal 14. This entire structure (including the compensation to the proportional and integral parts of the phase error) can be considered to be a modified digital loop filter 335.

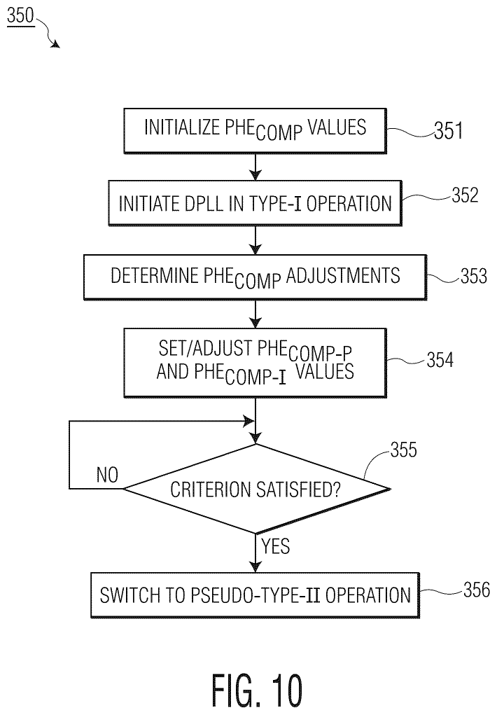

FIG. 10 illustrates an exemplary process 350 for operating the control structure 300, e.g., including the setting of certain control and/or input signals by one or more control processors (not shown). Initially, in step 351, PHE_{COMP-P} 330 and PHE_{COMP-I} 331 are set to initial values. In the preferred embodiments: (1) PHE_{COMP-P} 330 and PHE_{COMP-I} 331 are set to an initial value, e.g., zero or values derived from PHE_{COMP} 130, with PHE_{COMP} 130 having been generated as described above.

In step 352, the DPLL of which control structure 300 is a part is initiated in Type-I operation, i.e., with integrator 76 disabled by control signal 336. Steps 353 and 354 preferably are then performed (e.g., depending upon the embodiment), as follows.

In step 353, a characteristic phase value is first determined, preferably using one of the techniques discussed above in connection with the determination of PHE_{COMP} 130 in step 153. Next, based on that characteristic phase value, an integral-phase-compensation (IPC) value is identified, with that value preferably being a multiple of 2× in a phase-domain representation and, more preferably, corresponding to the negative value of the multiple of 2× that is closest to PHE_{COMP} 130 (i.e., PHE_{COMP} 130 rounded to the nearest multiple of 2× multiplied by −1). It is noted that, whenever the present disclosure refers to a value that is a multiple of 2×, the reference refers to an integer multiple of 2×, and the value preferably is simply stored as the integer multiple (with the 2× value being implied). Also, a proportional-phase-compensation (PPC) value is determined, preferably as (or based on) the difference between PHE_{COMP} 130 and the IPC value, corresponding to the residual compensation value.

In step 354, the values of PHE_{COMP-P} 330 and PHE_{COMP-I} 331 are set or adjusted, as applicable, based on the values determined in step 353. Preferably, this step is performed by simply adding the PPC value determined in step 353 to the previous value of PHE_{COMP-P} 330 and adding the IPC value determined in step 353 to the previous value of PHE_{COMP-I} 331.

In step 355, a determination is made as to whether a specified criterion has been satisfied. This criterion and the considerations pertaining to it preferably are the same as those discussed in relation to the criterion discussed in connection with step 255 above, but with references to PHE 225 with references to PHE 325. If the specified criterion has been satisfied, then processing proceeds to step 356. If not, the process 350 waits at this step 355 until the criterion is satisfied.

In step 356, the DPLL switches to Pseudo-Type-II operation, by using control signal 336 to enable the integrator 76.

Summarizing, in the preferred embodiments, control structure 300 is started in Type-I operation, i.e., with the integrator 76 disabled using control signal 336, and values for PHE_{COMP-P} 330 and PHE_{COMP-I} 331 are determined during such Type-I operational stage. Then, upon completion of such determinations, the identified values are applied. Shortly thereafter, the integrator 76 is enabled using signal 336, so that control structure 300 begins operating in Pseudo-Type-II mode, with the same values of PHE_{COMP-P} 330 and PHE_{COMP-I} 331 being applied, thereby causing PHE 325 to converge to an integer multiple of 21.

### Proportional Integral Controller (PIC).

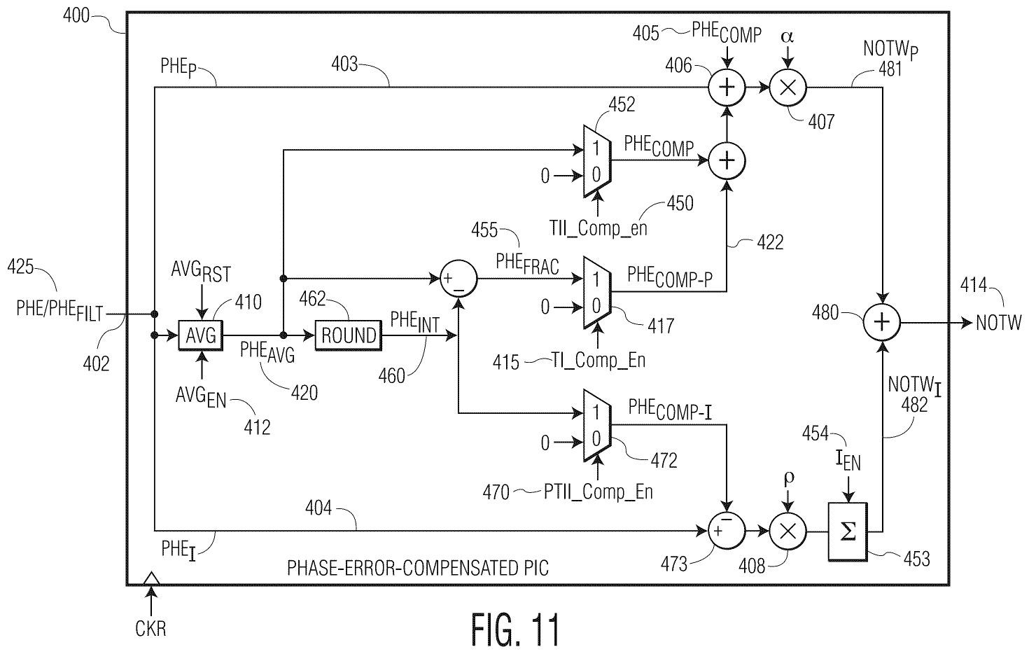

The preceding discussion separately covered structures and corresponding processes for operating a DPLL in each of several different operational modes: Type-I, Type-II and Pseudo-Type-II. The present section discusses a Proportional Integral Controller (PIC) 400, shown in FIG. 11, that can replace any of modified digital loop filters 135, 235 or 335 and allow the resulting DPLL to be reconfigured, as desired, using control and/or input signals provided by one or more control processors (not shown), to operate in any such mode, while implementing structures and techniques according to the present invention. As with the other digital loop filters discussed herein, PIC 400 typically also will include one or more low-pass filters (not shown), usually infinite impulse response (IIR) filters, to reduce noise. Instead, as with such other digital loop filters, the present discussion and drawings focus on the distinguishing features of the present invention over the prior art, which mainly reside in the control aspects.

As shown, input 402 receives the phase error signal (PHE) 425 (e.g., any of PHE 125, 225 or 325), which is then provided on proportional path 403 and integral path 404. As discussed above, the various components of PIC 400 are selectively enabled in order to provide the desired operational sequences. In the preferred embodiments, all or almost all of such components are disabled initially, so that the DPLL operates in Type-I mode, meaning that PHE 425 is effectively only provided through the proportional path 403 (with or without initial compensation, as discussed in the following sentence), including through gain element 407 (applying a gain of α), so as to provide the proportional part of the NOTW 414, i.e., NOTW_{P} 481. As discussed above, a mathematically predicted proportional phase compensation value PHE_{COMP} 405 (e.g., based on knowledge of some or all of the feedback loop parameters and/or characteristics) optionally is calculated and/or otherwise determined (e.g., experimentally) in advance and used as an initial compensation (through adder 406). Also, averaging module 410 is enabled (using average-enable control signal 412) during this Type-I operational mode; however, in certain embodiments, it is not enabled immediately upon startup of the DPLL, but rather is delayed a short period of time in order to bypass the initial transient in the PHE 425 signal. In the current embodiment, averaging module 410 calculates the average value over the specified number of cycles, e.g., 128 samples in the currently preferred embodiment. However, in alternate embodiments, any other characteristic phase value, as discussed above, instead may be determined in module 410.

Once the averaging operation has been completed, TI_Comp_En signal 415 preferably is provided, so that the output of multiplexer 417 changes from 0 to the fractional part PHE_{FRAC} 455 of PHE_{AVG} 420 instead is used to supplement PHE_{COMP} 405 (if any), with PHE_{AVG} 420 being the output of averaging module 410, and fractional part PHE_{FRAC} 455 corresponding to or representing the fractional part of the phase error, with the integer part PHE_{INT} 460 having been generated in rounding module 462. Thereafter, as discussed above, the DPLL remains in Type-I mode until a specified criterion has been satisfied (e.g., preferably corresponding to stabilization of the PHE 425 signal). Once the criterion has been satisfied, e.g., depending upon the specific embodiment, PIC 400 preferably transitions to Pseudo-Type-II operation, as follows:

If Type-II operation is desired, in the current embodiment:
the TII_Comp_En signal 450 is set to enable multiplexer 452, so that PHE_{AVG} 420 instead is used to supplement PHE_{COMP} 405 (if any); and
the integrator 453 is enabled (through integrator-enable signal 454) after the convergence criterion (discussed above in connection with step 355) has been satisfied, meaning that the integral path 404 becomes active (with PHE 425 supplied to integrator 453 through integral gain element 408, which applies a gain of ρ), so as to provide the integral part of the normalized oscillator tuning word, i.e., NOTW_{I} 482.

If Pseudo-Type-II operation is desired, in the current embodiment:
the PTII_Comp_En signal 470 and TI_Comp_En signal 415 are asserted, either at the same time or sequentially, with the former enabling multiplexer 472, so that PHE_{INT} 460 is used to modify PHE 425 on the integral path 404 (in subtractor 473); and
the integrator 453 is enabled (through integrator-enable signal 454) after the convergence criterion (discussed above in connection with step 355) has been satisfied, meaning that the integral path 404 becomes active (with the difference between PHE 425 and PHE_{INT} 460 supplied to integrator 453 through integral gain element 408).

Regardless of the mode of operation, adder 480 combines NOTW_{P} 481 and NOTW_{I} 482 (if any) to provide the NOTW 414. Several additional notes are as follows.

Generally speaking, during Type-I operation (i.e., integral path 404 off), without compensation the DPLL cannot lock for fractional parts outside the acquisition range of the phase detector. Several options exist, e.g.:
Option 1: arbitrarily choose a PHE_{COMP} 405 value, leading to a lock with PHE 425=−PHE_{COMP} 405

Option 2: PHE_{AVG} 420 is snapped and applied in a feedforward manner to PIC proportional path 403, leading to a lock close to a null PHE 425, depending on the accuracy of the snapped value; in this case, the compensation value can be large, leading to risk of saturation of the DCO control word 414 which causes a slew rate limited response of the loop, slowing down the locking time.
Option 3 (the approach discussed above): only the fractional part of PHE_{AVG} 420 (i.e., PHE_{FRAC} 455) is snapped and applied in a feedforward manner to the PIC proportional path 403, leading to a lock close to an integer PHE 425, depending on the accuracy of the snapped value, with only ±0.5 PHE to compensate for, leading to fast compensation and fast locking without risk of saturation and slew-rate-limited convergence.

In certain embodiments, Pseudo-Type-II operation begins in Type-I mode, and Type-I compensation is implemented based on Option 3 above, so that PHE_{COMP-P} 422=PHE_{AVG} 420−round (PHE_{AVG} 420).

The integer part PHE_{INT} 460 of PHE_{AVG} 420 preferably is snapped and subtracted from the PIC integral path 404 before the accumulator 453, i.e., PHE_{COMP-I}=−round (PHE_{AVG} 420)

### Additional Considerations.

As used herein, the term “coupled”, or any other form of the word, is intended to mean either directly connected or connected through one or more other components, elements or processing blocks, e.g., for the purpose of preprocessing. In the drawings and/or the discussions of them, where individual steps, components, modules or processing blocks are shown and/or discussed as being directly connected to each other, such connections should be understood as couplings, which may include additional steps, components, modules, elements and/or processing blocks. Unless otherwise expressly and specifically stated otherwise herein to the contrary, references to a signal herein mean any processed or unprocessed version of the signal. That is, specific processing steps discussed and/or claimed herein are not intended to be exclusive; rather, intermediate processing may be performed between any two processing steps expressly discussed or claimed herein, except to the extent expressly stated otherwise.

Whenever a specific value is mentioned herein, such a reference is intended to include that specific value or substantially or approximately that value. In this regard, the foregoing use of the word “substantially” is intended to encompass values that are not substantially different from the stated value, i.e., permitting deviations that would not have substantial impact within the identified context. For example, stating that a continuously variable signal level is set to a particular value should be understood to include values within a range around such specifically stated value that produce substantially the same effect as the specifically stated value. For example, the identification of a single length, width, depth, thickness, etc. should be understood to include values within a range around such specifically stated value that produce substantially the same effect as the specifically stated value. As used herein, except to the extent expressly and specifically stated otherwise, the term “approximately” can mean, e.g.: within +10% of the stated value or within +20% of the stated value.

In the preceding discussion, the terms “operators”, “operations”, “functions” and similar terms refer to method or process steps or to hardware components, depending upon the particular implementation/embodiment.

In the event of any conflict or inconsistency between the disclosure explicitly set forth herein or in the accompanying drawings, on the one hand, and any materials incorporated by reference herein (whether explicitly or by operation of any applicable law, regulation or rule), on the other, the present disclosure shall take precedence. In the event of any conflict or inconsistency between the disclosures of any applications or patents incorporated by reference herein, the disclosure most recently added or changed shall take precedence.

Unless clearly indicated to the contrary, words such as “optimal”, “optimize”, “maximize”, “minimize”, “best”, as well as similar words and other words and suffixes denoting comparison, in the above discussion are not used in their absolute sense. Instead, such terms ordinarily are intended to be understood in light of any other potential constraints, such as user-specified constraints and objectives, as well as cost and processing or manufacturing constraints.

In the above discussion, certain methods are explained by breaking them down into steps listed in a particular order. Similarly, certain processing is performed by showing and/or describing modules arranged in a certain order. However, it should be noted that in each such case, except to the extent clearly indicated to the contrary or mandated by practical considerations (such as where the results from one step are necessary to perform another), the indicated order is not critical but, instead, that the described steps and/or modules can be reordered and/or two or more of such steps (or the processing within two or more of such modules) can be performed concurrently.

References herein to a “criterion”, “multiple criteria”, “condition”, “conditions” or similar words which are intended to trigger, limit, filter or otherwise affect processing steps, other actions, the subjects of processing steps or actions, or any other activity or data, are intended to mean “one or more”, irrespective of whether the singular or the plural form has been used. For instance, any criterion or condition can include any combination (e.g., Boolean combination) of actions, events and/or occurrences (i.e., a multi-part criterion or condition).

Similarly, in the discussion above, functionality sometimes is ascribed to a particular module or component. However, functionality generally may be redistributed as desired among any different modules or components, in some cases completely obviating the need for a particular component or module and/or requiring the addition of new components or modules. The precise distribution of functionality preferably is made according to known engineering tradeoffs, with reference to the specific embodiment of the invention, as will be understood by those skilled in the art.

As used herein, the words “include”, “includes”, “including”, and all other forms of the word should not be understood as limiting, but rather any specific items following such words should be understood as being merely exemplary.

Several different embodiments of the present invention are described above and/or in any documents incorporated by reference herein, with each such embodiment described as including certain features. However, it is intended that the features described in connection with the discussion of any single embodiment are not limited to that embodiment but may be included and/or arranged in various combinations in any of the other embodiments as well, as will be understood by those skilled in the art.

Thus, although the present invention has been described in detail with regard to the exemplary embodiments thereof and accompanying drawings, it should be apparent to those skilled in the art that various adaptations and modifications of the present invention may be accomplished without departing from the intent and the scope of the invention. Accordingly, the invention is not limited to the precise embodiments shown in the drawings and described above. Rather, it is intended that all such variations not departing from the intent of the invention are to be considered as within the scope thereof, as limited solely by the claims appended hereto.

### System Environment.

In general, it should be noted that, except as expressly noted otherwise, any process, method, functionality, module, block, unit or similar item referenced herein can be implemented by a general-purpose processor executing computer-executable process steps (e.g., software and/or firmware), by dedicated (e.g., logic-based) hardware, or any combination of these approaches, with the particular implementation being selected based on known engineering tradeoffs. That is, where any process and/or functionality described above is implemented in a fixed, predetermined and/or logical manner, it can be accomplished by a processor executing programming (e.g., software or firmware), an appropriate arrangement of logic components (hardware), or any combination of the two, as will be readily appreciated by those skilled in the art. In other words, it is well-understood how to convert logical and/or arithmetic operations into instructions for performing such operations within a processor and/or into logic gate configurations for performing such operations; in fact, compilers typically are available for both kinds of conversions.

It should be understood that the present invention also relates to machine-readable tangible (or non-transitory) media on which are stored software or firmware program instructions (i.e., computer-executable process instructions) for performing the methods and functionality and/or for implementing the modules and components of this invention. Such media include, by way of example, magnetic disks, magnetic tape, optically readable media such as CDs and DVDs, or semiconductor memory such as various types of memory cards, USB flash memory devices, solid-state drives, etc. In each case, the medium may take the form of a portable item such as a miniature disk drive or a small disk, diskette, cassette, cartridge, card, stick etc., or it may take the form of a relatively larger or less-mobile item such as a hard disk drive, ROM or RAM provided in a computer or other device. As used herein, unless clearly noted otherwise, references to computer-executable process steps stored on a computer-readable or machine-readable medium are intended to encompass situations in which such process steps are stored on a single medium, as well as situations in which such process steps are stored across multiple media.

What is claimed is:

1. A phase-lock loop, comprising:
an oscillator having an input for receiving a control signal and an output for providing an output signal having a frequency based on the control signal;
a phase detector having a first input for receiving a reference signal, a second input coupled to the output of the oscillator for receiving a feedback signal, and an output for providing a phase-error signal that is indicative of a phase difference between the reference signal and the feedback signal; and
a loop filter having a first input coupled to the output of the phase detector, a second input for receiving a proportional-phase-compensation value, and an output for providing the control signal to the oscillator,
wherein the control signal comprises a proportional component which is a combination of the phase-error signal and the proportional-phase-compensation value.

2. The phase-lock loop according to claim 1, wherein the proportional component is produced by adding the phase-error signal and the proportional-phase-compensation value to provide a result and then applying a gain to the result.

3. The phase-lock loop according to claim 1, wherein the proportional-phase-compensation value has been determined based on a previous value of the phase-error signal.

4. The phase-lock loop according to claim 3, wherein the phase-compensation value has been determined based on an average of previous values of the phase-error signal.

5. The phase-lock loop according to claim 3, wherein the proportional-phase-compensation value has been determined by low-pass filtering the phase-error signal during a prior operational period of the phase-lock loop.

6. The phase-lock loop according to claim 1, wherein the proportional-phase-compensation value has been determined mathematically, in advance, based on loop characteristics.

7. The phase-lock loop according to claim 1, wherein:
the phase-lock loop begins operating in a first operational phase, during which the proportional-phase-compensation (PPC) value is set at a first PPC value, and
after a first period of time, the proportional-phase-compensation value is updated to a second PPC value based on the phase-error signal during the first operational phase.

8. The phase-lock loop according to claim 7, wherein the first PPC value is 0.

9. The phase-lock loop according to claim 7, wherein the first PPC value has been determined mathematically, in advance, based on loop characteristics.

10. The phase-lock loop according to claim 7, wherein the second PPC value is determined by at least one of: (a) averaging values of the phase-error signal during at least a portion of the first operational phase, or (b) low-pass filtering the phase-error signal during at least a portion of the first operational phase.

11. The phase-lock loop according to claim 7, wherein the loop filter also includes an integrator which, when enabled, provides an integral component of the control signal, and wherein the integrator is disabled, such that the integral component is 0, until satisfaction of a specified criterion following completion of the first period of time, at which point the integrator is enabled.

12. The phase-lock loop according to claim 11, wherein the specified criterion comprises the end of a predetermined additional second period of time.

13. The phase-lock loop according to claim 11, wherein the specified criterion comprises a condition on the phase-error signal after the proportional-phase-compensation value has been updated to the second value.

14. The phase-lock loop according to claim 13, wherein the specified criterion comprises at least one of: (a) a magnitude of at least one value of the phase-error signal falling within a specified range; or (b) variation in the phase-error signal falling below a specified threshold.

15. The phase-lock loop according to claim 11, wherein when the integrator is enabled, the integrator accumulates uncompensated values of the phase-error signal.

16. The phase-lock loop according to claim 11, wherein when the integrator is enabled, the integrator accumulates modified phase-error signal values that are a combination of the phase-error signal and an integral-phase-compensation (IPC) value.

17. The phase-lock loop according to claim 16, wherein the integral-phase-compensation value is determined based on the phase-error signal during the first operational phase.

18. The phase-lock loop according to claim 17, wherein: (a) a characteristic phase value is determined based on the phase-error signal during the first operational phase; (b) the integral-phase-compensation value is set at a multiple of 2× in a phase-domain representation; and (c) the second PPC value is set as a difference between the characteristic phase value and the integral-phase-compensation value.

19. The phase-lock loop according to claim 18, wherein the integral-phase-compensation value is set to the multiple of 2× in the phase-domain representation nearest to the characteristic phase value.

20. A tangible medium storing computer-readable, computer-executable process steps for controlling a phase-lock loop that includes an adder having a first input coupled to a phase-error signal output by phase-detector, a second input, and an output that provides a proportional-phase-compensation value, wherein said process steps include steps to:
begin operating the phase-lock loop in a first operational phase, during which a first value is provided to the second input of the adder; and
after a first period of time, instead providing a second value to the second input of the adder,
wherein the second value is based on the phase-error signal during the first operational phase.
